(19) United States
(12) Patent Application Publication
(10) Pub. No.: US 2009/0056792 A1
(43) Pub. Date: Mar. 5, 2009

(54) Interconnecting support panel providing substantially planar upper surface

(76) Inventor: Ted H. Salyer, Tulare, CA (US)

Correspondence Address: RICHARD A. RYAN;ATTORNEY AT LAW, 8497 N. MILLBROOK AVENUE, SUITE 101, FRESNO, CA, 93720, US

(21) Appl. No.: 11/897,371

(22) Filed: Aug. 29, 2007

(51) Int. Cl. H01L 31/042

(52) U.S. Cl. 136/251

(57) ABSTRACT

An interconnecting support panel configured to be utilized with a support structure to provide a substantially planar upper surface on which a work object may be beneficially attached or mounted. In a preferred use of the support panel, the work object is a photovoltaic element, such as photovoltaic laminate strips, which can be attached to the planar upper surface in a manner that does not place shade thereon. In a preferred configuration, the support panel has a panel member with opposing ends and sides and the planar upper surface. A first side has a downwardly projecting first connector and a second side has a downwardly projecting second connector. The first and second connectors are configured to cooperatively engage the opposite configured connectors on adjoining support panels. If desired, an endcap at one end of the support panel provides a raceway for wires connecting the photovoltaic elements.

### CROSS-REFERENCE TO RELATED APPLICATIONS

None.

### BACKGROUND OF THE INVENTION

A. Field of the Invention

The field of the present invention relates generally to structures made up of a plurality of interconnecting panels for supporting one or more useful objects, such as a layer of photovoltaic laminate strips. More particularly, the present invention relates to an interconnecting panel that is configured to join with an adjacent panel to provide a substantially planar surface to support a plurality of objects. Even more particularly, the present invention relates to such interconnecting panels that are configured join together to form a planar surface that provides improved span capabilities and does not interfere with the operation of the object(s) supported thereby.

B. Background

Support structures are commonly utilized in many different types of situations to beneficially support one or more useful objects in a position that allows the object to perform its function and/or the user to more easily access the useful objects. Often it is particularly beneficial or even necessary that the support structure have a generally planar upper surface to or on which the useful object is attached or mounted. An example of a useful object that typically can benefit by being supported by a support structure having a generally planar upper surface is the photovoltaic component(s) of a solar energy electrical generating system. As concerns over the use, cost and availability of fossil fuels continue to rise, the desire to utilize readily available, silent, nonpolluting solar power as a source of electrical energy also increases. Over the years, many people have utilized rooftops and other locations on building structures as the support structure for the solar energy components. More recently, the economics of solar energy systems has allowed persons to consider the use of a dedicated, stand-alone structure to support the solar energy system components.

Many people are at least generally or somewhat familiar with the use of rigid conventional solar cells as the photovoltaic component of the solar energy producing system. One of the relatively recent improvements to solar energy technology is the use of thin film photovoltaic devices to generate the electricity from the solar energy system. Typically, these thin film photovoltaic devices, also referred to as photovoltaic laminates, are encapsulated in a transparent, durable, flexible and UV stabilized polymer, such as ETFE. The polymer ETFE, which is commercially available as Tefzel®, is known to be a particularly durable and high-light-transmissive polymer. Due to their flexible nature, thin film photovoltaic devices have been formed into “solar shingles” or strips for use as or in conjunction with other roofing material. An example of such shingles are the Uni-Solar® available from United Solar Ovonic. Typically, such photovoltaic devices are provided in a stick-on configuration that is rolled out on to a support surface, which may be a roof, and then connected together in series by joining the wires that extend from the photovoltaic laminate strip at one end thereof.

As stated above, although most solar energy systems have been attached to or incorporated into a building structure, stand-alone installations of solar energy systems have, relatively recently, become much more economical to install. In fact, the planned or constructed size some stand-alone systems is so large that they are commonly referred to as “solar energy farms.” Because they do not rely on a building structure, stand-alone installations require their own support structure to support the photovoltaic component, such as the photovoltaic laminates. Naturally, any support structure should be configured so as to receive the photovoltaic component in a manner that most benefits the solar collection aspect of the component, namely supporting the photovoltaic component in an upwardly manner in the general direction of the sun.

Presently, the support structure commonly utilized for photovoltaic components incorporates the standard standing seam roof panel, an example of which is identified by numeral 1 and shown as Prior Art in FIG. 1. The standing seam roof panel 1 comprises a panel member 2 that is configured to interconnect with adjoining roof panels to provide the desired support structure. The panel member 2 has a first interconnection component 3 disposed along its first side 4 and a second interconnection component 5 disposed along its second side 6. First 3 and second 5 interconnection components are cooperatively configured such that the second interconnection component 5 is placed over the first interconnection component 3 to form the standing seam that gives the panel member its name. As a result of the configuration, the combined upper surfaces 7 of the standing seam roof panels 1 creates a series of valleys and ridges, with the interconnection components 3/5 forming the ridges and the spaces between being the valleys. When used as part of the support structure for photovoltaic laminates that make up a solar energy system, the photovoltaic laminate strips (not shown in FIG. 1) are affixed to the portion of the upper surface 7 between the seams, which is made up of the joined first 3 and second 5 interconnection components. Typically, the standing seam roof panel 1 is attached to a plurality of support posts and cross-members (not shown) that support the roof panels 1 above the ground or other surface.

The use of standing seam roof panels 1 as the upward supporting component of a support structure utilized to support the photovoltaic components of a solar energy systems has a number of significant limitations. One such limitation is that the standing seam resulting from interconnected panels 2 will result in shade covering a portion of the photovoltaic component during at least part of the day, resulting in loss of electrical generating efficiency. Another limitation with standing seam roof panels 1 is that they are generally somewhat limited with regard to the distance which they are able to span unsupported. Because of these and other limitations, what is needed is an improved support panel that can be utilized as the supporting component of a support structure to support a useful object. The preferred support panel should be configured to interconnect with adjoining cooperatively configured panels to provide an upper surface on which to place or attach a useful object. Preferably, the support panel should be able to interconnect with a select number of adjoining like-configured panels to provide the desired width for the upper surface on which the object is positioned. The preferred support panel should provide a generally planar upper surface to facilitate placement of the object thereon and to improve the performance of certain types of useful objects by not shading the objects, such as strips of photovoltaic laminates that are the photovoltaic component of a solar energy system. Preferably, the support panel should be configured to be less limited with regard to the distance which it is able to span unsupported by support posts, cross-members and like structural components.

### SUMMARY OF THE INVENTION

The interconnecting support panel of the present invention solves the problems and provides the benefits identified above. That is to say, the present invention discloses a support panel which is configured to be the supporting component of a support structure on or to which a useful object can be placed or attached. The support panel of the present invention can be interconnected with other like-configured support panels to obtain the desired width of upper surface on which can be placed or attached one or more useful objects, such as a plurality of photovoltaic laminate strips. The support panel of the present invention interconnects with other like-configured support panels to provide a generally planar surface on which a useful object can be beneficially placed or attached thereto. In the preferred embodiments, the interconnecting components of adjacent support panels interconnect in a manner that forms the generally planar surface. The support panel is also configured to be less limited with regard to the distance it is able to span unsupported by support posts, cross-members and other structural components of the support structure.

In one general aspect of the present invention, the interconnecting support panel is configured for use in a support structure to support one or more work objects, such as photovoltaic elements comprising photovoltaic laminate strips. The support panel has a panel member with opposing first and second ends, opposing first and second sides and a substantially planar upper surface disposed between the ends and sides. Located at the first side of the panel member, typically integral therewith, is a generally downwardly projecting first connector having a downwardly disposed section and an angled upward section. Located at the second side of the panel member, also typically integral therewith, is a generally downwardly projecting second connector having a downwardly disposed section, a substantially horizontal section and a generally upward section. The first connector and second connector are both shaped and configured to cooperatively join with an adjacent support panel so as to maintain the generally planar upper surface in a generally planar configuration so as to beneficially support the work object thereon. The support panel can include an endcap that defines a raceway therein for substantially enclosing wires extending from the work objects, such as the photovoltaic laminate strips, and directed to use or distribution of electricity therefrom. The support panel can be attached to one or more frame members of the support structure.

Accordingly, the primary objective of the present invention is to provide an interconnecting support panel that provides the advantages discussed above and overcomes the disadvantages and limitations associated with presently available support panels and support structures.

It is also an important object of the present invention to provide an interconnecting support panel that is configured to interconnect with adjacent support panels in a manner that forms the desired supporting surface on which to place or attach useful objects.

It is also an important object of the present invention to provide an interconnecting support panel that has interconnecting components on the sides thereof that interconnect with adjacent support panels in a manner which defines a substantially planar upper surface.

It is also an important object of the present invention to provide an interconnecting support panel that improves the operation and/or efficiency of a useful object placed on or attached to a substantially planar upper surface defined by two or more interconnecting support panels.

It is also an important object of the present invention to provide an interconnecting support panel that is particularly configured to beneficially receive one or more photovoltaic laminate strips thereon in a manner which facilitates full exposure of such strips to the sun by eliminating components that can cause shade to be placed over the photovoltaic components.

It is also an important object of the present invention to provide an interconnecting support panel that increases the distance such panel can span between support posts, cross-members or other structural frame members of the structural support system.

The above and other objectives of the present invention will be explained in greater detail by reference to the attached figures and the description of the preferred embodiment which follows. As set forth herein, the present invention resides in the novel features of form, construction, mode of operation and combination of processes presently described and understood by the claims.

### BRIEF DESCRIPTION OF THE DRAWINGS

In the drawings which illustrate the preferred embodiments and the best modes presently contemplated for carrying out the present invention:

FIG. 1 is an end perspective view of a prior art support panel in the form of a standing seam roof panel;

FIG. 2 is an end perspective view of an interconnecting support panel configured according to a preferred embodiment of the present invention;

FIG. 3 is a side view of an installed support structure having the interconnecting support panel of FIG. 2 supporting a photovoltaic laminate strip;

FIG. 4 is an end view of the center of the installed support structure of FIG. 3 showing four interconnecting support panels joined together;

FIG. 5 is an isolated end view of the interconnecting component on the left side of the interconnecting support panel of FIG. 2;

FIG. 6 is an isolated end view of the interconnecting component on the right side of the interconnecting support panel of FIG. 2; and

FIG. 7 is an isolated end view of the interconnecting components joined together as in FIG. 4.

### DETAILED DESCRIPTION OF THE PREFERRED EMBODIMENTS

With reference to the figures where like elements have been given like numerical designations to facilitate the reader's understanding of the present invention, the preferred embodiments of the present invention are set forth below. The enclosed figures are merely illustrative of a preferred embodiment and represent one of several different ways of configuring the present invention. Although specific components, materials, configurations and uses are illustrated, it should be understood that a number of variations to the components and to the configuration of those components described herein and in the accompanying figures can be made without changing the scope and function of the invention set forth herein. For instance, although the figures and description provided herein are primarily described as being utilized to support a plurality of photovoltaic laminate strips as part of a solar energy system, those skilled in the art will readily understand that this is merely for purposes of simplifying the present disclosure and that the present invention is not so limited.

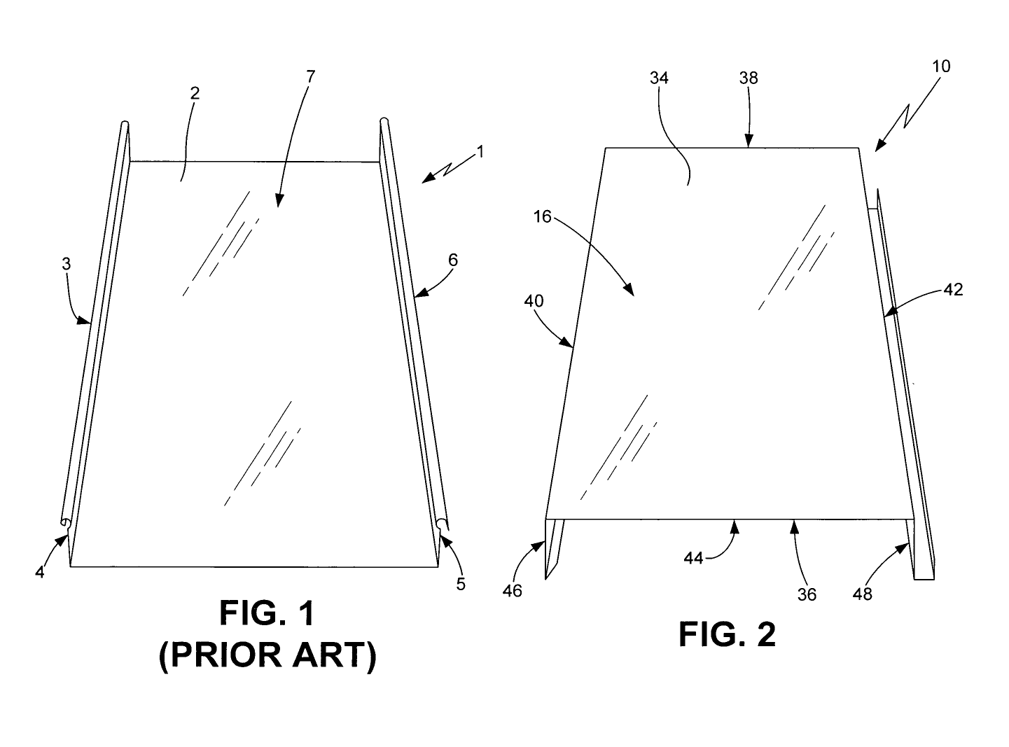

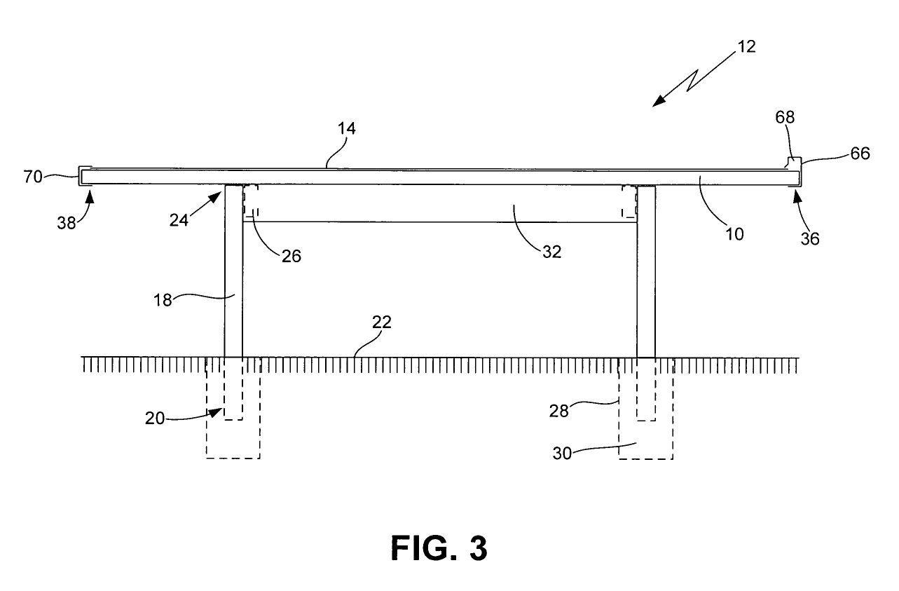

An interconnecting support panel that is manufactured out of the components and configured pursuant to a preferred embodiment of the present invention is shown generally as 10 in FIGS. 2 through 4. As shown in FIG. 3, support panel 10 is configured to be utilized as part of a support structure 12 that is utilized to beneficially support a useful object, such as one or more strips of photovoltaic laminates 14 that are part of a solar energy electrical producing system. As discussed in more detail below, because support panels 10 provide a substantially planar top surface 16 the effectiveness and efficiency of the sun on the photovoltaic laminate strips 14 will not be reduced by shading that otherwise results from the upwardly projecting interconnection components 3 and 5 of the prior art standing seam roof panel 1 shown in FIG. 1. As shown in FIG. 3, support structure 12 comprises a plurality of frame members, such as support posts 18 and cross-members 26. Support posts 18 have a lower end 20 secured in the ground 22 or onto another surface and an upper end 24 connected to one or more of the cross-members 26 that support the support panel 10 of the present invention. In the embodiment shown in FIG. 3, the lower end 20 of support posts 18 are secured in an upright position by being mounted in a hole 28 filled with concrete 30 or like material. Alternatively, the posts could be bolt down to a concrete or like slab or other post support systems could be utilized. An end closure member 32 extends between a pair of cross-members 26, as shown in FIG. 3, to prevent the cross-members from twisting in their cantilever condition. As will be readily appreciated by those skilled in the art, a variety of different configurations of support structure 12 can be configured for use with support panel 10 of the present invention to support the support panel 10 in the desired angle relative to the ground 22 (i.e., horizontal as shown or it can be placed at an angle if desired). As such, the support structure 12 shown, utilizing the support posts 18 and cross-members 26 is not intended to limit the scope support panel 10 of the present invention.

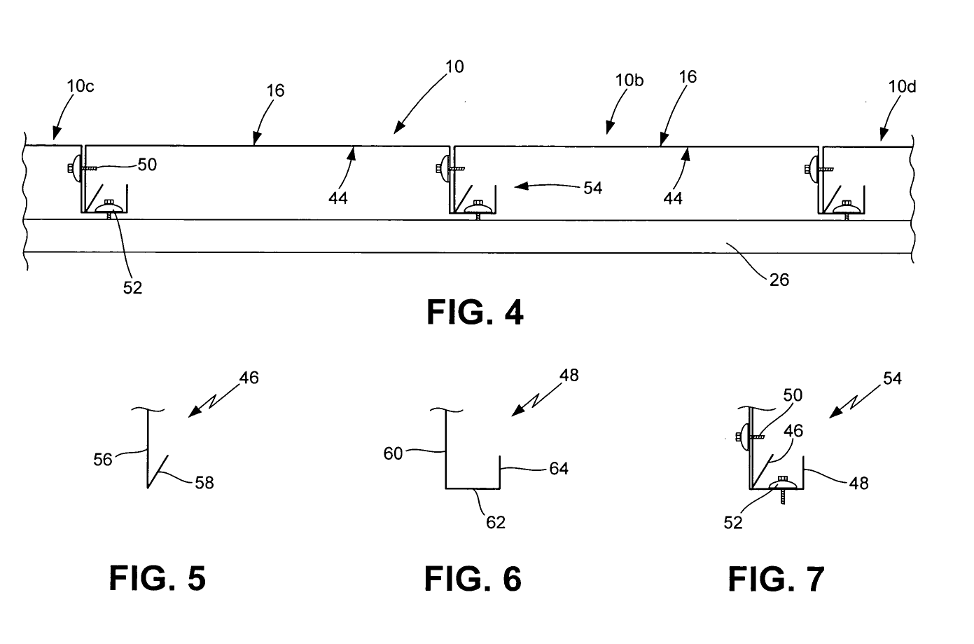

Support panel 10, as best shown in FIGS. 2 and 4, comprises a panel member 34 having a first end 36, opposing second end 38, a first side 40, opposing second side 42, upper surface 16 and lower surface 44. Preferably, upper surface 16 is at least substantially planar such that when adjacent support panels, such as second 10b and third 10c support panels shown in FIG. 4, are interconnected to first support panel 10, as described below, a substantially planar surface is formed across the adjacent support panels (e.g., 10, 10b, 10c and 10d). Although not shown in FIG. 4, in a preferred use of the present invention a photovoltaic laminate strip 14 is affixed to the planar upper surface 16 of each of the support panels 10, 10b, 10c and 10d as part of a solar energy electrical production system. Although not required for the preferred use of support panel 10, lower surface 44 can also be substantially planar. If desired or necessary for structural support, lower surface 44 can be ribbed or otherwise configured to provide more longitudinal strength. As will be readily apparent to those skilled in the art, panel member 34 can be of a variety of different sizes or configurations. Because the typical photovoltaic laminate strip 14 is configured in a generally rectangular shape having longer sides 40/42 than ends 36/38, such as dimensions of approximately 15-½ inches wide by a 18 feet long, a preferred configuration for panel member 34 is approximately 16 inches wide by 19 feet long. Naturally, other configurations and sizes of photovoltaic element 14 will be beneficially placed on or attached to the upper surface 16 of panel member 34 of other, corresponding configuration and dimensions. Panel member 34 can be made out of a variety of different materials and of different gauges of material. For instance, the present inventor has found that the use of 18 to 22 gauge Galvalume® (55% Aluminum-Zinc alloy coated sheet steel) or Zincalume® materials or SMP or Kynar 500® type finish or the like painted over the Galvalume® or Zincalume® material to be suitable for support panel 10 of the present invention.

To join with adjacent, like-configured support panels, such as 10b and 10c, support panel 10 of the present invention also comprises a first connector 46 at the first side 40 of panel member 34 and a second connector 48 at the second side 42 of panel member 34. In the preferred embodiment, both first 46 and second 48 connectors are integral with panel member 34 and are formed therewith during the manufacturing process 48. As shown in FIGS. 2 and 4, both first 46 and second 48 connectors are generally downward projecting from and relative to panel member 34 so as to maintain the planar nature of the abutting substantially planar upper surfaces 14 on each of the adjacent support panels 10, 10b, 10c and 10d. The downward projecting first 46 and second 48 connectors are cooperatively configured such that the first connector 46 of support panel 10 is engaged by the second connector 48 of support panel 10c, the first connector 46 of support panel 10b is engaged by the second connector 48 of support panel 10, as shown in FIG. 4. In the embodiment shown in the figures, first connector 46 is received in second connector 48 and the two connectors are joined, using a first attachment device 50 and a second attachment device 52, to form a joined connector 54, as shown in FIGS. 4 and 7. In the embodiment shown in the figures, first 50 and second 52 attachment devices are a self-drilling, stainless steel screw with a seal washer. Those skilled in the art will appreciate that a variety of different attachment devices 50/52 can be utilized to sufficiently join first 46 and second 48 connectors together so that wind or other environmental issues will not blow over or otherwise damage support structure 12 and the photovoltaic laminate strips 14 supported thereon.

In a preferred embodiment of support panel 10 of the present invention, first 46 and second 48 connectors are cooperatively configured to be joined together in a manner that does not impede or otherwise interfere with the placement and attachment of first 50 and second 52 attachment devices. As best shown in FIGS. 4 through 7, first connector 46 has a downwardly disposed section 56 connected at one end to first side 40 and an angled upward section 58 connected at the end of the downwardly disposed section 56 and second connector 48 has a downwardly disposed section 60, a substantially horizontal section 62 and a substantially upward section 64. As shown in FIGS. 4 and 7, joined member 54 has the bottom of the downwardly disposed section 56 abutting the horizontal section 62 and the angled upward section 58 directed upward in a manner that does not impede or otherwise interfere with the access to first attachment device 50 that joins the downwardly disposed section 56 of first connector 46 to the downwardly disposed section 60 of the second connector 48 and to second attachment device 52 that joins the horizontal section 62 of second connector 48 to a cross-member 26 (or other component of support structure 12). In this manner, the adjacent support panels, such as 10 and 10b, are joined together and the support panels 10/10b are joined to the underlying structural members of support structure 10. As shown in FIG. 4, the support panels 10, 10b, 10c and 10d are joined in a manner that maintains the planar upper surfaces 16 in an adjacent configuration, which for use with photovoltaic elements 14 prevents shade from reducing the efficiency of the solar generating system. Although the above sets forth the preferred configuration for joining support panels 10 together, those skilled in the art will readily appreciate that variations thereto can be made and still accomplish the objectives of the support panel 10 of the present invention.

In a preferred configuration and use of support panels 10 of the present invention and support structure 12 utilizing these panels, which is to beneficially support one or more photovoltaic elements 14, a specially configured endcap 66 is positioned at the first ends 36 of the support panels to define a raceway 68 for the collection and passage of wires from photovoltaic elements 14 and a C-shaped trim member 70 is placed at the second ends 38 of the various support panels 10. If endcap 66 is utilized, the raceway 68 allows the user to protect the wires that extend from and then connect in series the various photovoltaic elements 14 on support panels 10 and the wires that connect the photovoltaic elements 14 to devices, machines or apparatuses that are powered by the electricity generated thereby or to distribution systems (i.e., power grid) that distribute the electricity for use at other locations.

In use, the support structure 12 is constructed by utilizing appropriate frame members, such as posts 18 and cross-members 26, to form a frame-like structure for receiving support panel 10 of the present invention. If desired, the lower end 20 of the posts 18 can be placed in a hole 28 that is filled with concrete 30 or like material to secure posts 18 in a generally upright position or the posts 18 can be bolted to a concrete slab to obtain the desired configuration for the posts 18. With the basic frame installed, the various support panels, such as 10, 10b, 10c and 10d, are placed on top in a manner that they interconnect with each other at the first 40 and second 42 sides thereof and are secured to the frame of the support structure 12 in a manner that maintains the generally planar configuration of generally planar surface 16. In the preferred embodiment, as set forth above, second attachment device 52 is utilized to secure second connector 48 to cross-member 26 or another secure portion of the frame and first connector 46 is placed within second connector 48 and first attachment device 50 is utilized to attach adjacent support panels, such as 10 and 10b, together. With support panels 10 attached to the structural members the photovoltaic elements 14, such as photovoltaic laminate strips, are affixed to the planar upper surface of support panels 10. In a preferred embodiment, endcap 66 is placed at first end 36 to provide a raceway 68 for the wires which interconnect the various photovoltaic elements 14 and to transfer the power collected thereby for use or distribution. A C-shaped trim member 70 is then placed at second end 38.

While there are shown and described herein specific forms of the invention, it will be readily apparent to those skilled in the art that the invention is not so limited, but is susceptible to various modifications and rearrangements in design and materials without departing from the spirit and scope of the invention. In particular, it should be noted that the present invention is subject to modification with regard to any dimensional relationships set forth herein and modifications in assembly, materials, size, shape, and use. For instance, there are numerous components described herein that can be replaced with equivalent functioning components to accomplish the objectives of the present invention.

What is claimed is:

1. A support panel, comprising:
a panel member having a first end, a second end, a first side, a second side and a substantially planar upper surface;
a generally downwardly projecting first connector at said first side of said panel member; and
a generally downwardly projecting second connector at said second side of said panel member,
wherein each of said first connector and said second connector are shaped and configured to cooperatively join with an adjacent support panel so as to maintain said generally planar upper surface in a generally planar configuration to beneficially support a work object thereon.

2. The support panel according to claim 1, wherein said support panel is configured as part of a support structure having one or more frame members supporting said support panel.

3. The support panel according to claim 2, wherein said work object is one or more photovoltaic elements.

4. The support panel according to claim 3, wherein said photovoltaic elements comprise photovoltaic laminate strips.

5. The support panel according to claim 4 further comprising an endcap disposed at either said first end or said second end of said support panel, said endcap defining a raceway therein.

6. The support panel according to claim 1, wherein said first connector comprises a downwardly disposed section and an angled upward section.

7. The support panel according to claim 6, wherein said second connector comprises a downwardly disposed section, a substantially horizontal section and a generally upward section.

8. The support panel according to claim 1, wherein said second connector comprises a downwardly disposed section, a substantially horizontal section and a generally upward section.

9. A support panel for use in a support structure to support one or more photovoltaic elements, said support panel comprising:
a panel member having a first end, a second end, a first side, a second side and a substantially planar upper surface;
a generally downwardly projecting first connector at said first side of said panel member, said first connector having a downwardly disposed section and an angled upward section; and
a generally downwardly projecting second connector at said second side of said panel member, said second connector having a downwardly disposed section, a substantially horizontal section and a generally upward section,
wherein each of said first connector and said second connector are shaped and configured to cooperatively join with an adjacent support panel so as to maintain said generally planar upper surface in a generally planar configuration to beneficially support said photovoltaic elements thereon.

10. The support panel according to claim 9, wherein said photovoltaic elements comprise photovoltaic laminate strips.

11. The support panel according to claim 10 further comprising an endcap disposed at either said first end or said second end of said support panel, said endcap defining a raceway therein.

12. A support structure for supporting one or more work objects, said support structure comprising:
one or more frame members;
a plurality of support panels attached to at least one of said one or more frame members, said plurality of support panels comprising at least a first support panel, a second support panel and a third support panel, each of said support panels having a panel member with a first end, a second end, a first side, a second side and a substantially planar upper surface;
a generally downwardly projecting first connector at said first side of each of said panel members, said first connector having a downwardly disposed section and an angled upward section; and
a generally downwardly projecting second connector at said second side of each of said panel members, said second connector having a downwardly disposed section, a substantially horizontal section and a generally upward section,
wherein said the first connector of said second support panel is received in the second connector of said first support panel and the first connector of said first support panel is received in the second connector of said third support panel so as to maintain said generally planar upper surface in a generally planar configuration to beneficially support said work object thereon.

13. The support structure according to claim 12, wherein said work object is a photovoltaic element.

14. The support structure according to claim 13, wherein said photovoltaic element comprises photovoltaic laminate strips.

15. The support structure according to claim 14, wherein said support panel further comprises an endcap disposed at either said first end or said second end of said support panel, said endcap defining a raceway therein.

16. The support structure according to claim 12 further comprising a first attachment device connecting said first connector and said second connector and a second attachment device connecting said support panel to at least one of said plurality of frame members.
